(19) United States
(12) Patent Application Publication
(10) Pub. No.: US 2015/0155396 A1
(43) Pub. Date: Jun. 4, 2015

(54) SOLAR ANTENNA ARRAY AND ITS FABRICATION

(71) Applicants: Laurence H. COOKE, Los Gatos, CA (US); William J. ALLEN, Cupertino, CA (US)

(72) Inventors: Laurence H. COOKE, Los Gatos, CA (US); William J. ALLEN, Cupertino, CA (US)

(21) Appl. No.: 14/582,747

(22) Filed: Dec. 24, 2014

Related U.S. Application Data
(63) Continuation-in-part of application No. 13/454,155, filed on Apr. 24, 2012.

(51) Int. Cl. H01L 31/02; H01L 31/18; H01L 31/0475

(52) U.S. Cl. CPC H01L 31/0201; H01L 31/0475; H01L 31/186; H01L 31/18

(57) ABSTRACT

A solar antenna array may comprise an array of antennas that may capture and convert sunlight into electrical power. Methods for constructing the solar antenna array may use a stencil and self aligning semiconductor processing steps to minimize cost. Designs may be optimized for capturing a broad spectrum of visible light and non-polarized light. Testing and disconnecting defective antennas from the array may also be performed.

### CROSS-REFERENCE TO RELATED APPLICATIONS

This application is a continuation-in-part of U.S. patent application Ser. No. 13/454,155, filed on Apr. 24, 2012, the contents of which are incorporated by reference herein in their entirety.

### FIELD OF ENDEAVOR

Various aspects of this disclosure may pertain to an economical manufacturing process of visible light rectenna arrays for the conversion of solar energy to electricity.

### BACKGROUND

Rectifiers for AC to DC conversion of high frequency signals have been well known for decades. A particular type of diode rectifier when coupled to an antenna, called a Rectenna, has also been known for decades. More specifically, over 20 years ago, Logan described using an array of Rectennas to capture and convert microwaves into electrical energy in U.S. Pat. No. 5,043,739 granted Aug. 27, 1991. However, the dimensions of the antenna limited the frequency until recently, when Gritz, in U.S. Pat. No. 7,679,957 granted Mar. 16, 2010, described using a similar structure for converting infrared light into electricity, and Pietro Siciliano suggested that such a structure may be used for sunlight in “Nano-Rectenna For High Efficiency Direct Conversion of Sunlight to Electricity: by Pietro Siciliano of The Institute for Microelectronics and Microsystems IMM-CNR, Lecce (Italy).

Still, the minimum dimensions required for such visible light rectennas are generally in the tens of nanometers. While these dimensions can be accomplished by today's deep submicron masking technology, such processing is typically far more expensive than the current solar cell processes, which require much larger dimensions.

Still, as Logan pointed out in U.S. Pat. No. 5,043,739, the efficiency of microwave Rectennas can be as high as 40%, more than double that of typical single junction poly-silicon solar cell arrays, and when using metal-oxide-metal (MOM) rectifying diodes, as Pietro suggests, no semiconductor transistors are needed in the array core.

As such, it may be advantageous to be able to utilize the existing fine geometry processing capability of current semiconductor fabrication without incurring the cost of such manufacturing.

Also, recently, Rice University reported that their researchers created a carbon nanotube (CNT) thread with metallic-like electrical and thermal properties. Furthermore, single-walled carbon nanotube (SWCNT) structures are becoming more manufacturable, as described by Rosenberger et al. in U.S. Pat. No. 7,354,977 granted Apr. 8, 2008. Various forms of continuous CNT growth may have also been contemplated, such as Lemaire et. al. repeatedly harvesting a CNT “forest’ while it is growing in U.S. Pat. No. 7,744,793 granted Jun. 29, 2010, and/or put into practice using techniques described by Predtechensky et al. in U.S. Pat. No. 8,137,653 granted Mar. 20, 2012. Grigorian et al. describes continuously pushing a carbon gas through a catalyst backed porous membrane to grow CNTs in U.S. Pat. No. 7,431,985 granted Oct. 7, 2008.

Furthermore, others have contemplated using SWCNTs for various structures such as Rice University's CNT thread as described in “Rice's carbon nanotube fibers outperform copper,” by Mike Williams, posted on Feb. 13, 2014 at: http://news.rice.edu/2014/02/13/rices-carbon-nanotube-fibers-outperform-copper-2, magnetic data storage as described by Tyson Winarski in U.S. Pat. No. 7,687,160 granted Mar. 30, 2010, and in particular, antenna-based solar cells are described by Tadashi Ito et al. in US Patent Publication 2010/0244656 published Sep. 30, 2010. Still, Ito et al. did not describe methods to inexpensively construct carbon nanotube solar antennas for efficient conversion of solar energy.

### SUMMARY OF VARIOUS EMBODIMENTS

Various embodiments of the invention may relate to structures of rectenna arrays for converting sunlight into electricity and/or to ways to manufacture such structures, which may utilize self-aligning process steps and stencils made using current deep submicron IC masking techniques to achieve the fine dimensions required for the antennas.

The structure of the rectenna array may include an array of antennas connected to positive and negative rails by MOM diodes. The antennas may be of equal length, centered for maximum reception of green light.

In one embodiment, the rows of antennas may incrementally vary in length back and forth across the array between optimal reception of blue light and optimal reception of red light. Such optimal reception may consist of half-wavelength antennas that may vary from 220 nanometers to 340 nanometers in length. The rectenna array may be attached to a solid back surface, which may include a mirror for reflecting the light back to the array. It may also act as a ground plane, where the distance between the ground and antenna array in conjunction with the dielectric constant of the polymer between them may form an ideal strip-line antenna for visible light.

In another embodiment, a pair of arrays may be sandwiched together such that the respective layers of antenna are perpendicular to each other.

In one embodiment, a stencil may be created by a series of masked anisotropic V-groove etches with subsequent anti-adhesion depositions. A step of the process may include polishing the resist to allow the non-grooved portion of the silicon to be V-groove etched.

In another embodiment, the rectenna array may be fabricated using the stencil in successive metal deposition steps. The stencil may be angled or flat when used as a deposition target, and the deposition may be much less than the depth of the V-grooves in the stencil. The resulting metal may be peeled off the stencil using a polymer backing material. Additional layers may then be deposited on the polymer backed rectenna array.

In yet another embodiment the stencil may be repeatedly cleaned and reused.

In yet another embodiment the rectenna array may have redundant antennas, which if defective, may be disconnected by applying electricity through the array.

In another embodiment, carbon nanotube antennas maybe grown between metal lines comprised of a mixture of metal and metal oxide nano balls formed by the V-groove stencil.

### BRIEF DESCRIPTION OF THE DRAWINGS

Various embodiments of the invention will now be described in connection with the attached drawings, in which:

FIG. 1 is a logical diagram of an antenna array according to an embodiment of the invention,

FIGS. 2a, 2b and 2c are cross-sections of a stencil in the Y direction during its fabrication, according to an embodiment of the invention,

FIGS. 3a,3b,3c and 3d are cross-sections of a stencil in the X direction during its fabrication, according to an embodiment of the invention,

FIG. 4 is a diagram of a section of a stencil, according to an embodiment of the invention,

FIGS. 5a,5b,5c and 5d are cross-sections of an antenna array in the X direction during its fabrication, according to an embodiment of the invention,

FIGS. 6a, 6b and 6c are cross-sections of an antenna array in the Y direction during its fabrication, according to an embodiment of the invention,

FIG. 7 is a cross-section of a section of an antenna array, according to an embodiment of the invention,

FIG. 8 is a cross-section of two antenna arrays sandwiched together, according to an embodiment of the invention,

FIG. 9 is a top view of a section of an antenna array, according to an embodiment of the invention,

FIG. 10 is a top view of two antenna arrays sandwiched together, according to an embodiment of the invention,

FIGS. 11a and 11b are logical diagrams of an antenna array with defects before and after testing, according to an embodiment of the invention,

FIGS. 12a, 12b, and 12c are cross-sections of a stencil in the Y direction during its fabrication, according to an embodiment of the invention,

FIGS. 13a, 13b, 13c and 13d are cross-sections of a stencil in the X direction during its fabrication, according to an embodiment of the invention,

FIG. 14 is top cut away view of a section of a stencil, according to an embodiment of the invention,

FIGS. 15a through 15f are cross-sections of an antenna array during fabrication on the stencil, according to an embodiment of the invention,

FIGS. 16a, 16b and 16c are cross-sections of an antenna array during its fabrication after removal from the stencil, according to an embodiment of the invention,

FIG. 17 is another logical diagram of an antenna array according to an embodiment of the invention,

FIGS. 18a through 18d are cross-sections of another stencil fabrication according to an embodiment of the invention,

FIGS. 19a and 19b are diagrams of sections of stencils, according to embodiments of the invention,

FIGS. 20a through 20d are cross-sections of an antenna array during its fabrication, according to an embodiment of the invention,

FIGS. 21a through 21d are cross-sections of an antenna array during its fabrication, according to another embodiment of the invention,

FIGS. 22a and 22b are top views of two different configurations of the power and ground lines on solar array corresponding to the sections of stencils shown in FIGS. 19a and 19b,

FIG. 23 is a cross-section of an antenna array with defective carbon nanotube antennas,

FIG. 24 is an annotated cross-section of an antenna array, according to an embodiment of the invention, and

FIG. 25 is a cross-section of an antenna array with a cover plate, according to another embodiment of the invention.

### DESCRIPTION OF VARIOUS EMBODIMENTS

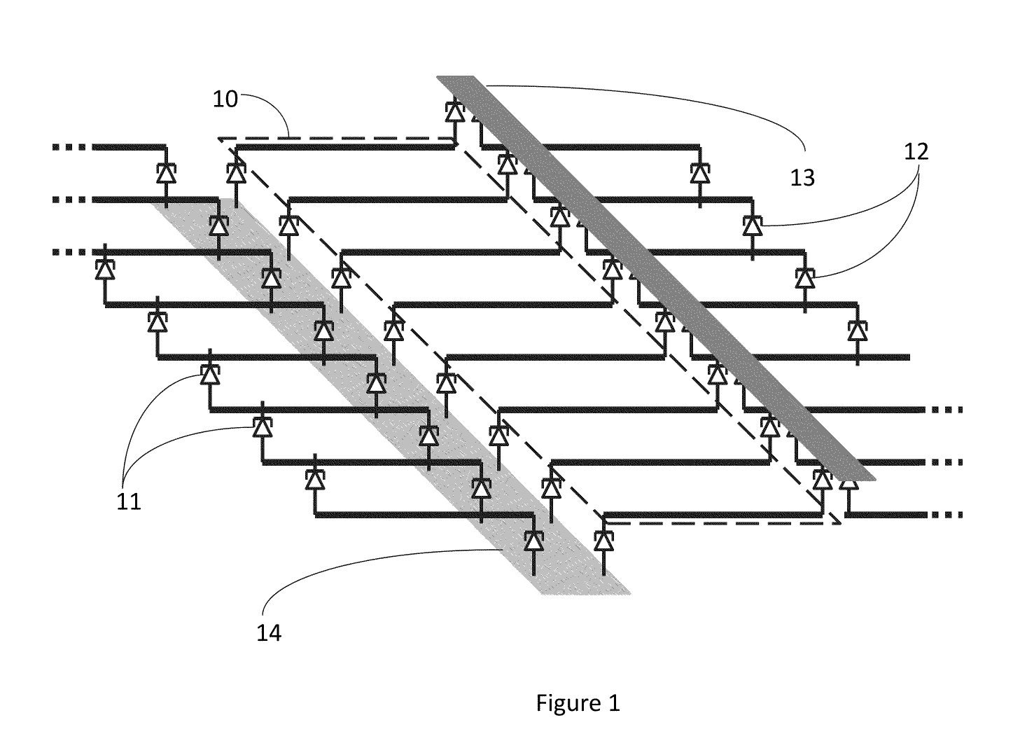

Embodiments of the present invention are now described with reference to FIGS. 1-24, it being appreciated that the figures may illustrate the subject matter of various embodiments and may not be to scale or to measure.

A logical diagram of an example of an embodiment of the present invention is shown in FIG. 1. The core of a solar antenna array may have rows of antennas 10, separated by power lines 13 and ground lines 14. The power and ground lines may be respectively coupled to the antennas by tunnel diodes 11 and 12. When the antennas are excited by visible light, the current may flow from the ground line to the power line, thus producing half-rectified electrical energy. It may be understood by one well-versed in the state of the art that additional circuitry, such as switching and decoupling capacitors, may be included in the periphery of the solar antenna array, as may be desired to produce stable DC power in voltages suited for commercial applications.

For antennas to efficiently receive visible light, it may be advantageous for them to be either ¼ or ½ of the wavelength of the light being captured, depending on whether or not the antenna is coupled to an existing ground plane. In order to produce such small structures, without expensive masking operations, one may create a stencil with which to manufacture the antennas.

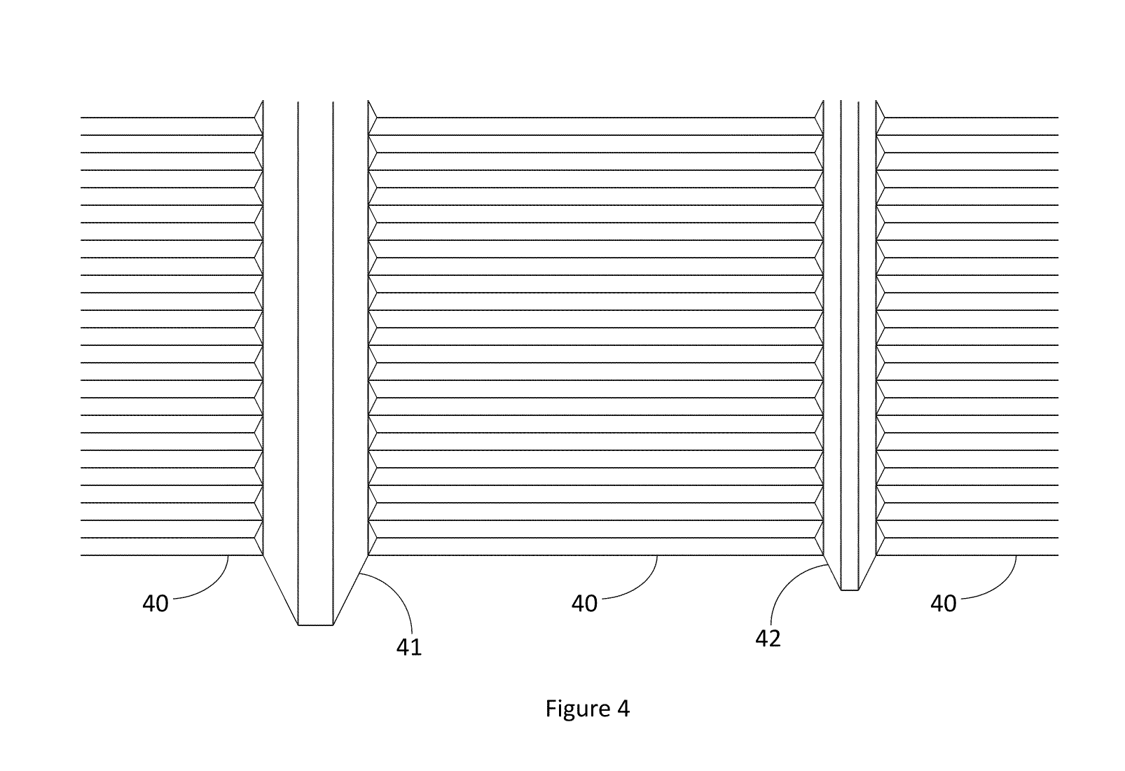

Reference is now made to FIG. 4, an example of a top view of one embodiment of such a stencil. The stencil may have rows of horizontal v-shaped grooves 40, bounded on either side by one large v-shaped ridge 41 and one small v-shaped ridge 42. These ridges may alternate across the antenna array. The stencil may be formed out of a silicon wafer with crystal orientation (1,1,1), for ease in producing the V-shaped structures.

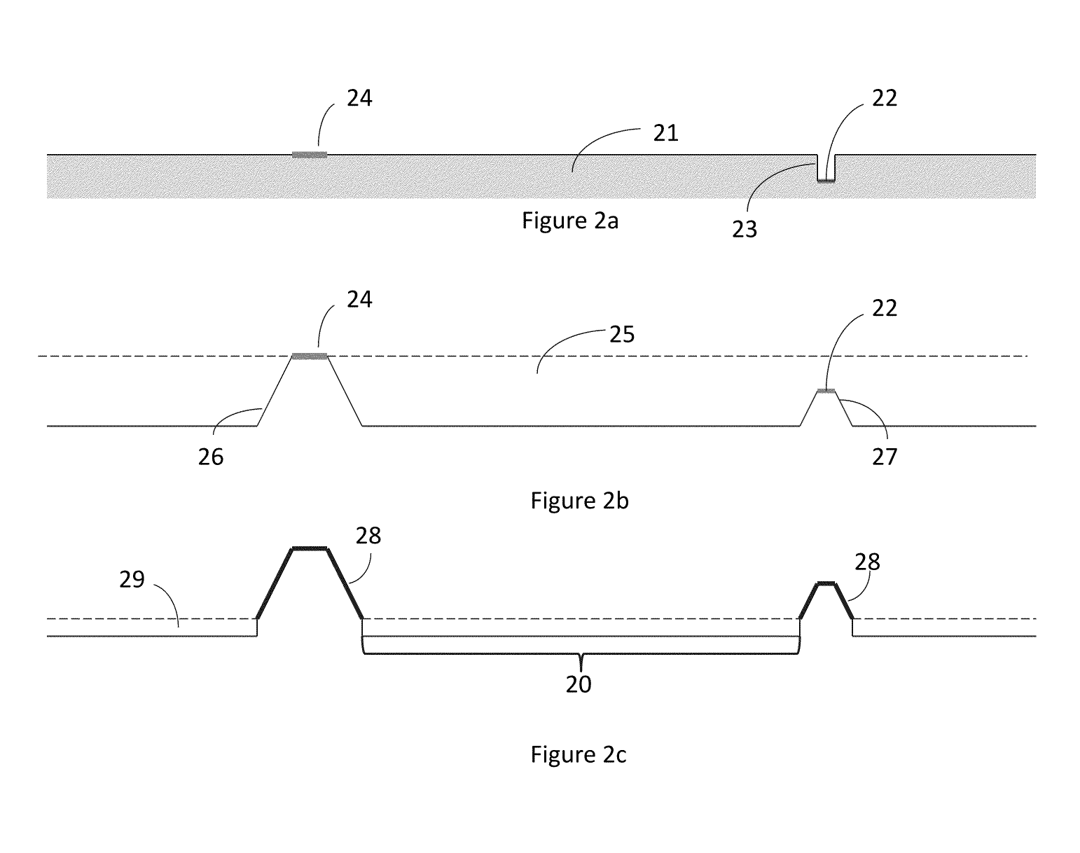

Reference is now made to FIGS. 2a, 2b and 2c, examples of cross-sections in the Y direction of a first set of steps that may be used to produce a stencil. Initially the silicon wafer 21 of FIG. 2a may be patterned with near-minimum-dimension lines in positive resist, which may be vertically etched to produce a series of small trenches 23. These trenches may subsequently have a layer of etch stop material 22, such as Silicon Oxide or Silicon Nitride, deposited on them. A similar pattern in negative resist may be formed, where the similar pattern may consist of near-minimum-dimension lines, deposited with, again, a layer of etch stop 24, that may be equally spaced between the trenches 23.

In a next step, shown in FIG. 2b, the resist lines 24 and deposited material 22 may form etch stops for a V-groove etch, which may remove a portion of the silicon wafer 25, leaving the alternating large 26 and small 27 ridges. Subsequently in FIG. 2c, a thin layer of etch stop may be deposited over the entire array, which may adhere to non-(1,1,1) silicon surfaces. A subsequent vertical etch may be used to remove all the etch stop from the horizontal surfaces between the ridges 28, along with a thin layer of silicon 29, leaving a thin layer of the etch stop deposited on the large and small ridges 28. It should be noted that the combination of the alignment of the masking steps to create the trench 22 and the resist line pattern 24 in FIG. 2a, along with the duration of the V-groove etch 25 in FIG. 2b may be used to produce the proper antenna length 20, in FIG. 2c.

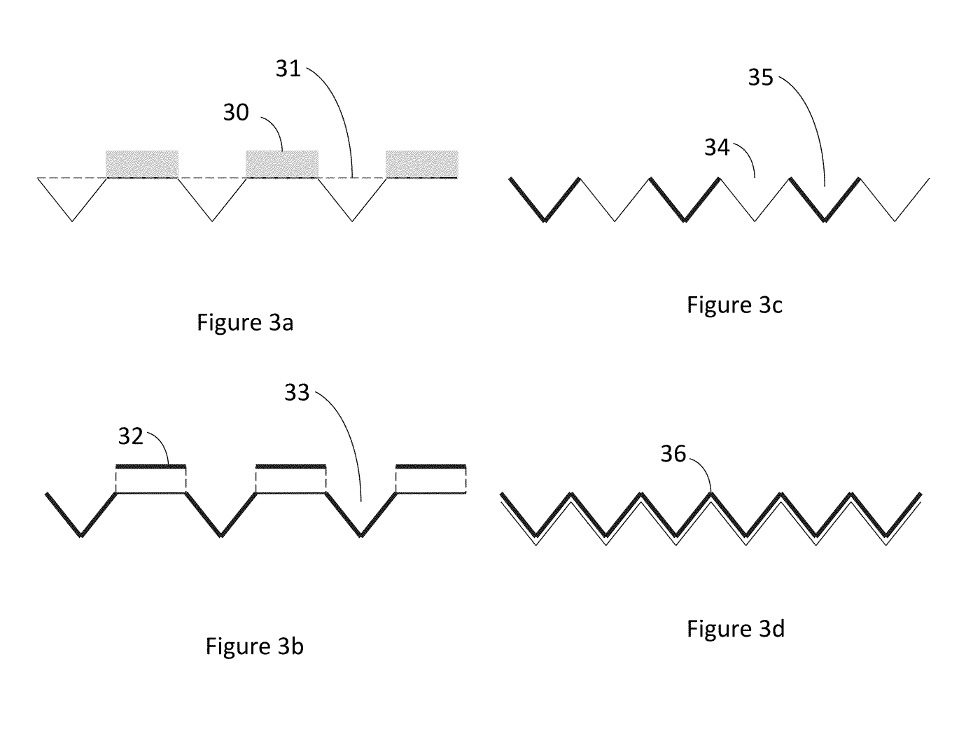

Reference is now made to FIGS. 3a, 3b, 3c and 3d, examples of cross-sections in the X direction of a second set of steps that may be used to produce a stencil. In FIG. 3a, a regular array of equal-width lines 30 and spaces may be patterned on the flat silicon surface between the small and large v-shaped ridges (which, for example, may be prepared as discussed above). A subsequent partial V-groove etch may form partial V-grooves 31 between the resist lines 30. This may not be a time critical step if a (1,1,1) silicon material is used because the etch may preferentially select the (1,1,1) surface of the silicon, stopping when the groove is complete. Then a thin layer etch stop material may be deposited in the etched V-grooves 33, removing the rest by lifting it off with the resist used to pattern the V-grooves 32, as shown in FIG. 3b. Performing another V-group etch, using the material in the existing V-grooves 35 as an etch stop, may serve to etch out new V-grooves 34, as shown in FIG. 3c. The resulting pattern of grooves may then be cleaned of the etch stop material and may subsequently be covered with a layer of material, which is non-adhesive to the metal antenna, such as Silicon Nitride 36, shown in FIG. 3d.

The alignment of the lines 30 between the v-shaped ridges need not be exact, so long as they are large enough to extend onto but not over the v-shaped ridges, because the initial V-groove etch in FIG. 3c may not affect the material 28 on the small and large ridges, shown in FIG. 2c. While it may be desirable to keep the lines 30 and spaces 31, shown in FIG. 3a, to a minimum size, it may not be critical; rather, it may be more important to keep the widths of the lines 30 and spaces 31 as equal as possible, to keep the depths of the V-grooves as equal as possible. As such, in another embodiment, if the line pitch may be held to a tighter tolerance than the line widths and spaces, the V-groove etch in FIG. 3b may be followed by a resist removal and a continued V-groove etch, producing half as many V-grooves that are twice as deep. In this case, the trenches formed in the Y direction may be enlarged to ensure the proper fabrication of the solar antenna array.

Solar antenna array stencils may be created out of partial or full silicon wafers. It is further contemplated that silicon ingots may be grown with the necessary orientation to be sliced into long panels, or single crystal silicon annealing may be performed on long panels of silicon deposited glass or other suitable structure. It is further contemplated that the size of the stencil need only be determined by the ability to reliably use and reuse it in the manufacture of solar antenna arrays.

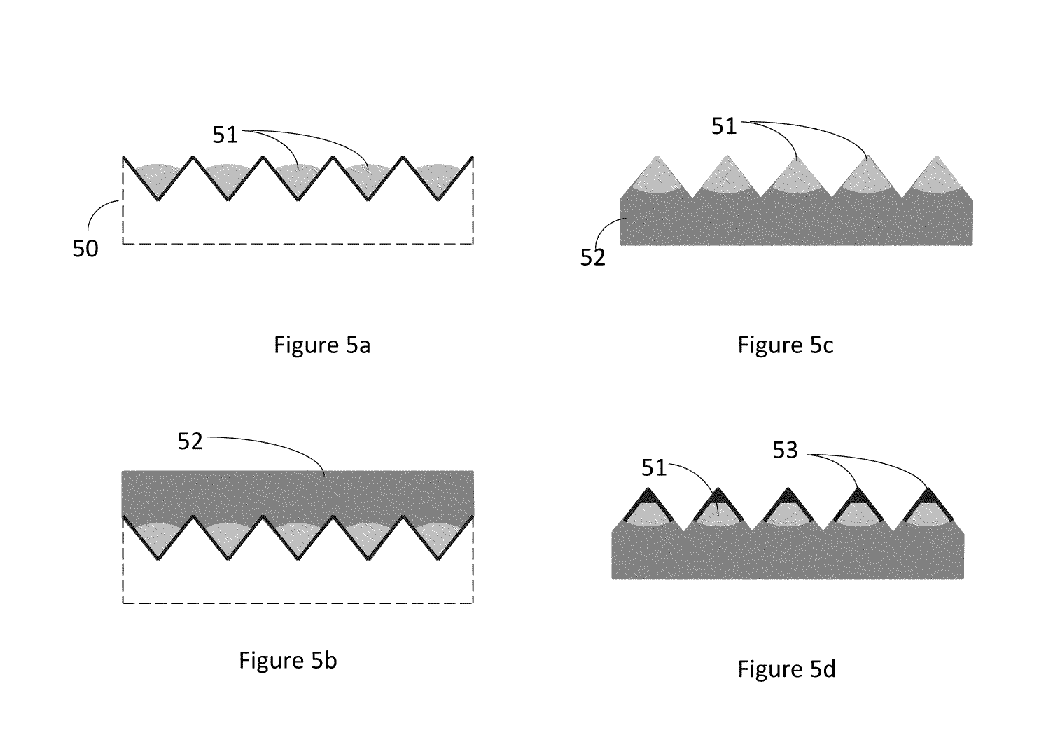

Reference is now made to FIGS. 5a,5b,5c, and 5d, examples of X direction cross-sections of a first set of steps that may be used in the manufacture of solar antenna arrays, according to an embodiment of the invention. FIG. 5a shows the result of deposition of a suitable conductive material onto the V-grooves of a stencil 50, forming conductive lines 51, which may become the antennas. This may be accomplished by using, for example, low pressure chemical vapor deposition (LPCVD) equipment. In one embodiment, Nickel may be used because it does not adhere to the Silicon Nitride stencil. In order to create a Metal Oxide Metal (MOM) rectifying diode that can handle terahertz frequencies, the cross-section of the material 51 may be formed with a ¼circle radius of less than 40 nm, but the V-groove size may be much larger because the amount of material is determined by the time of deposition, not the size of the V-groove. Forming a reasonable antenna array may require using a heated stencil, vibrating the stencil, or depositing the metal on a stencil angled at up to 45 degrees, or any combination of these processes. A layer of a polymer material 52, such as polyamide, may then be deposited on the stencil, as shown in FIG. 5b, and may then be cured sufficiently enough to enable peeling the polymer material 52 along with the conductive lines 51 off of the stencil, as shown in FIG. 5c. The peeling may be performed in the X direction, perpendicular to the antennas, to keep them from being broken by the peeling process. Then, a thin layer of oxide 53 may be grown on the conductive lines 51, as shown in FIG. 5d. The oxide layer may be less than 6 nm on the ends of the antennas.

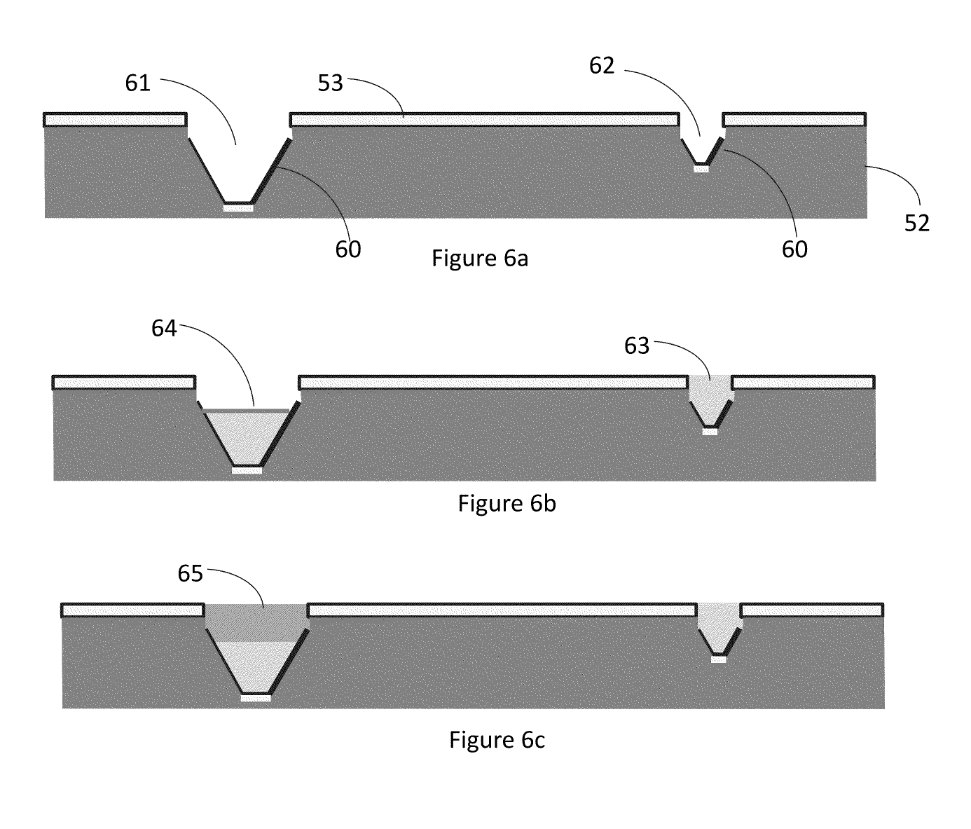

Reference is now made to FIGS. 6a, 6b, and 6c, examples of Y direction cross-sections of a second set of steps that may be used in the manufacture of Solar antenna arrays. As shown in FIG. 6a, when peeled off the stencil, the polymer material 52 may have large 61 and small 62 depressions from the large 41 and small 42 v-shaped ridges on the stencil as seen in FIG. 4. To keep the antennas 53 insulated from subsequent metal depositions, a thin cover glass layer 60 may then be deposited on the antenna array. In one embodiment, a short etch may be added to ensure the oxide on the ends of the antennas 53 are exposed. Next, as seen in FIG. 6b, the power line material 63 may be deposited and polished to remove the extraneous material from the antenna array leaving distinct power lines, as shown in FIG. 6b. A sufficient amount of material may be deposited to fill the small depression 62, but only partially fill the large depression 61. In another embodiment, a thin layer of non-adhesive material may be deposited/grown on the deposited material to allow for easy removal of the polishing debris, and another short etch may be added following polishing, to again ensure the oxide on the ends of the antennas 53 is exposed. As shown in FIG. 6c, the ground line material 65 may be deposited and polished off of portions of the array to form the ground lines in a manner similar to the process for the power lines, as shown in FIG. 6d. In another embodiment, the power and ground line materials may be malleable metals, such as Aluminum and Gold respectively.

In yet another embodiment of the fabrication process, the stencil may be cleaned, repaired as necessary, and reused for producing a plurality of antenna arrays.

It should be noted that the design of the stencil and associated antenna array process may be optimized to minimize the overall cost of the fabrication process by minimizing the cost of both the stencil and antenna array processes while maximizing the stencil reuse and antenna array yield.

In yet another embodiment of the stencil construction and antenna array process, most of the antenna array may be constructed on the stencil, and only polishing and applying a protective layer to the antenna array may then be performed after removing it from the stencil.

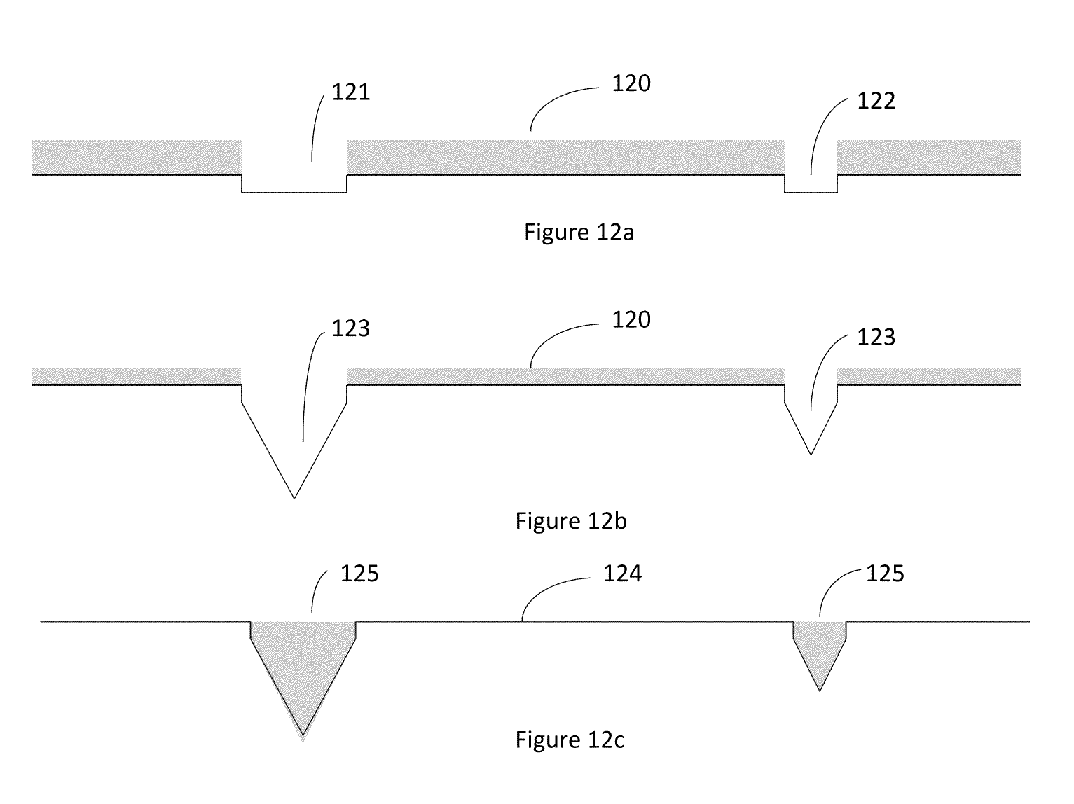

Reference is now made to FIGS. 12a, b and c, examples of Y direction cross-sections of a stencil during its fabrication, according to an embodiment of the invention. In this case, as shown in FIG. 12b, vertical sided v-grooves 123 may be etched by resist 120 masking, first a vertical etch for the power 122 and ground 121 lines, as shown in FIG. 12a, and then a V-groove etch 123, as shown in FIG. 12b. The resist may then be refilled into the V-groove trenches, 125 and polished off to expose the silicon 124, as shown in FIG. 12c. The resist may serve as an etch stop for the subsequent X direction etches.

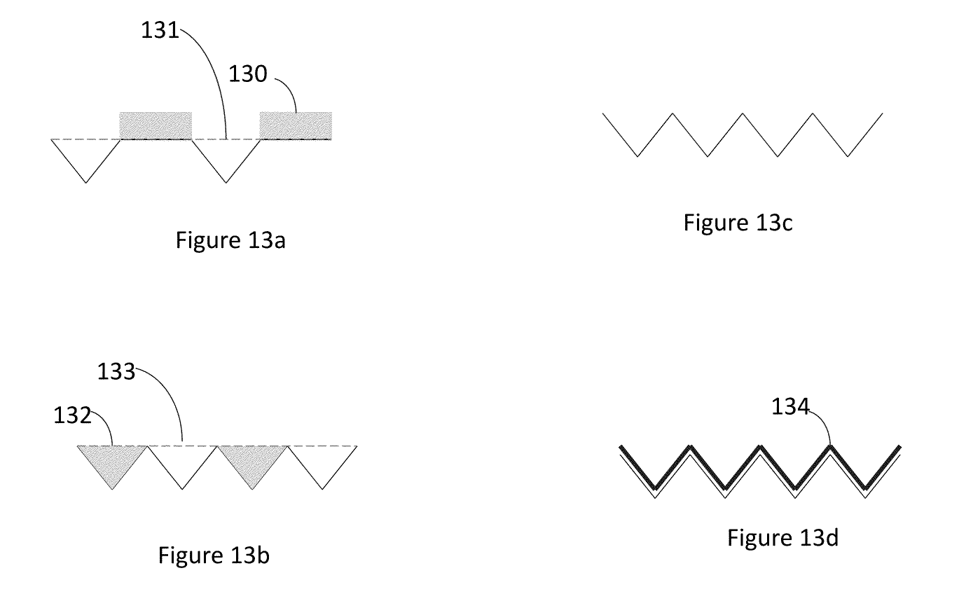

Reference is now made to FIGS. 13a, b, c and d, cross-sections of an example of a stencil in the X direction during its fabrication, according to an embodiment of the invention. A masked resist pattern 130 may be formed, which may be followed by a V-groove etch, as shown in FIG. 13a. Resist may then be reapplied and polished off, leaving resist in the existing V-grooves 132, and another V-groove etch may be performed, creating another set of V-grooves 133, as shown in FIG. 13b. The resist may then be removed, as shown in FIG. 13c, and a thin layer of non-adhesion material 134 may be applied to the stencil, as shown in FIG. 13d. Unlike the prior X direction V-groove process, as shown in FIGS. 3a, b, c and d, the current process need not require deposition of an etch stop or its subsequent lift off

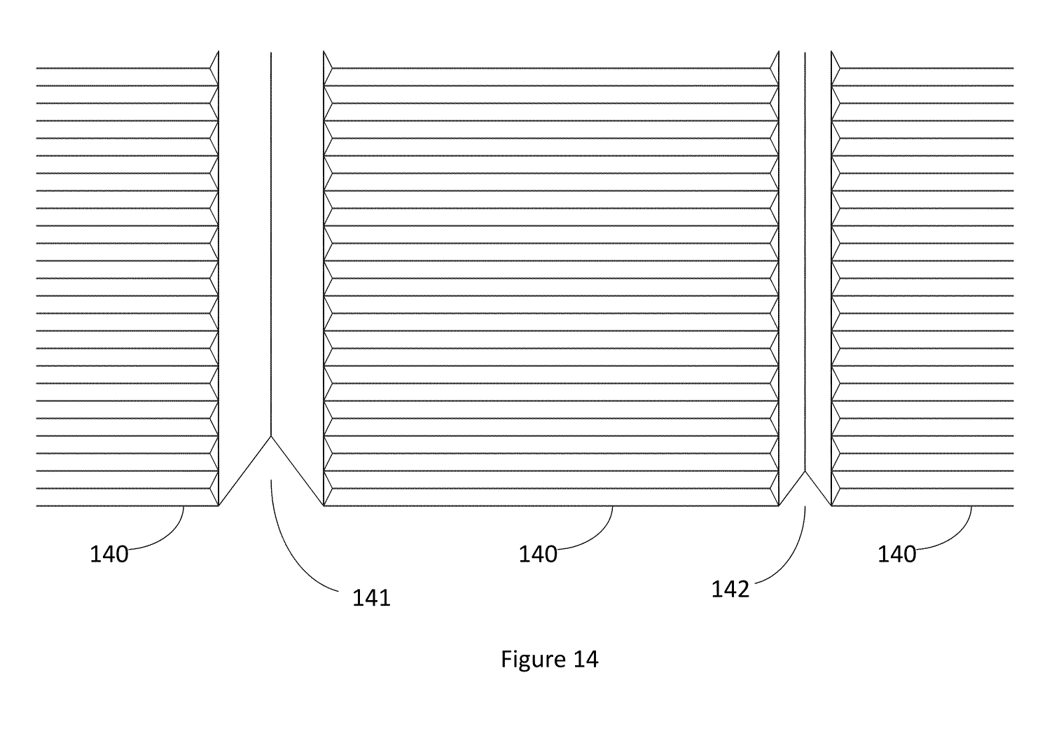

Reference is now made to FIG. 14, a top cut away view of an example of a section of a stencil, according to an embodiment of the invention. In this case, while the antenna X direction V-grooves 140 may be substantially the same as those 40 shown in FIG. 4, the V-groove trenches 141 and 142 may be inverted compared to the V-shaped ridges 41 and 42 shown in FIG. 4. This may serve to facilitate the deposition of the power and ground lines on the stencil, prior to removing the finished antenna array from the stencil.

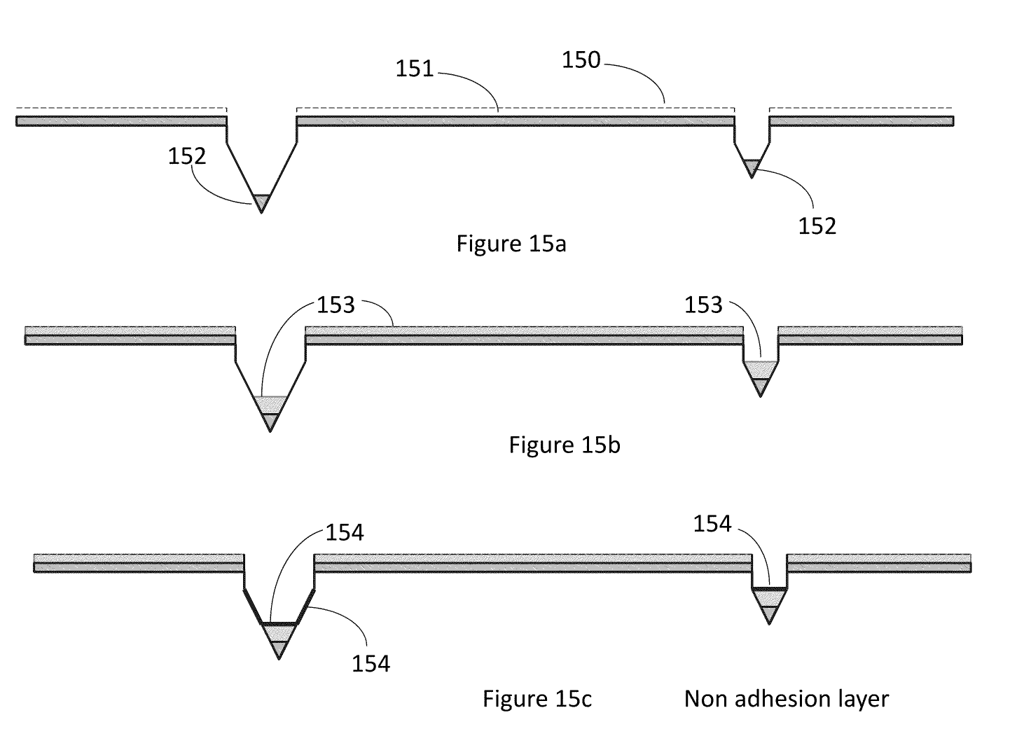

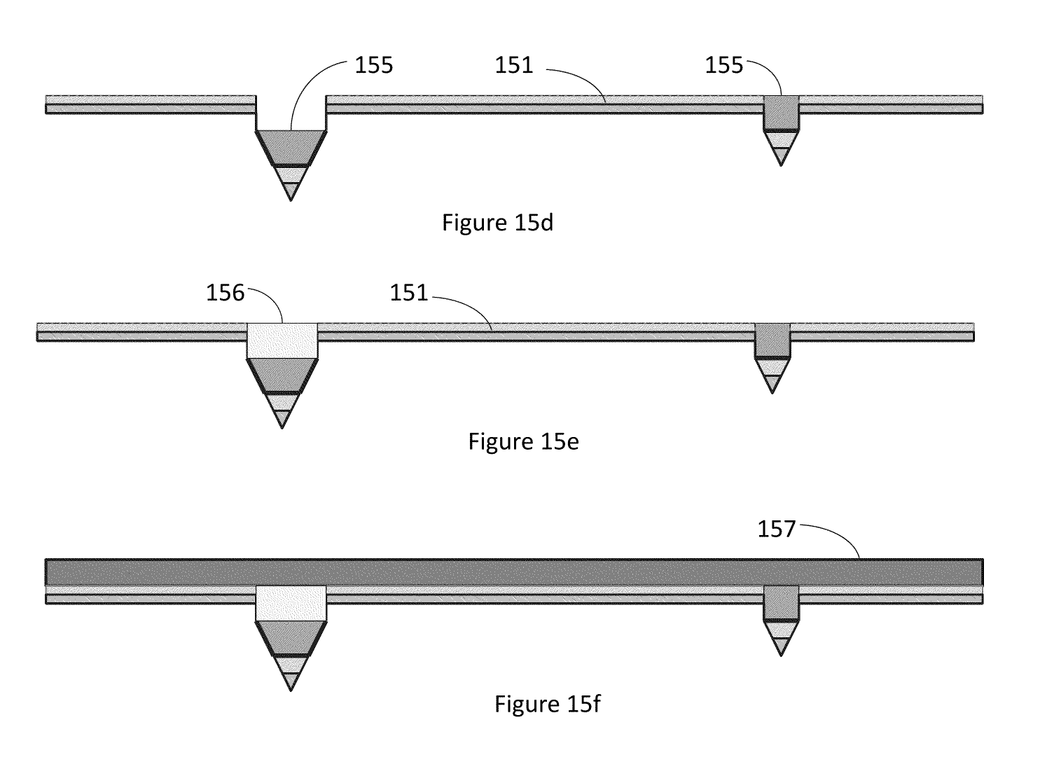

Reference is now made to FIGS. 15a through f, examples of cross-sections of an antenna array during fabrication on the stencil, according to an embodiment of the invention. Initially, as shown in FIG. 15a, a suitable conductive material, such as Nickel, may be deposited onto the stencil to form the antenna 151, including the bottom of the trenches 152, which may be followed by a thin oxide step. Next, as shown in FIG. 15b, cover glass may be deposited 153, which may be at least to the top of the X-direction V-grooves. In one embodiment, a short etch may be added to ensure the oxide on the ends of the antennas 151 is exposed. Ideally the glass and conductive layer below it may be chosen to not adhere to the non-adhesion layer, 134, as shown in FIG. 13d, on the stencil. Optionally, if the conductive materials for the power and ground lines are not easily removed from the existing non-adhesion layer, in the next step, a thin layer of another non-adhesion material 154 may be deposited, as shown in FIG. 15c. Then, in the same manner as the process shown in FIGS. 6a, b and c, The conductive material for the power lines 155 shown in FIG. 15d and the ground lines 156 shown in FIG. 15e may be respectively deposited and polished off (as needed). Then, a flexible polymer 157, shown in FIG. 15f, may be deposited to form a backing for peeling the antenna array off of the stencil.

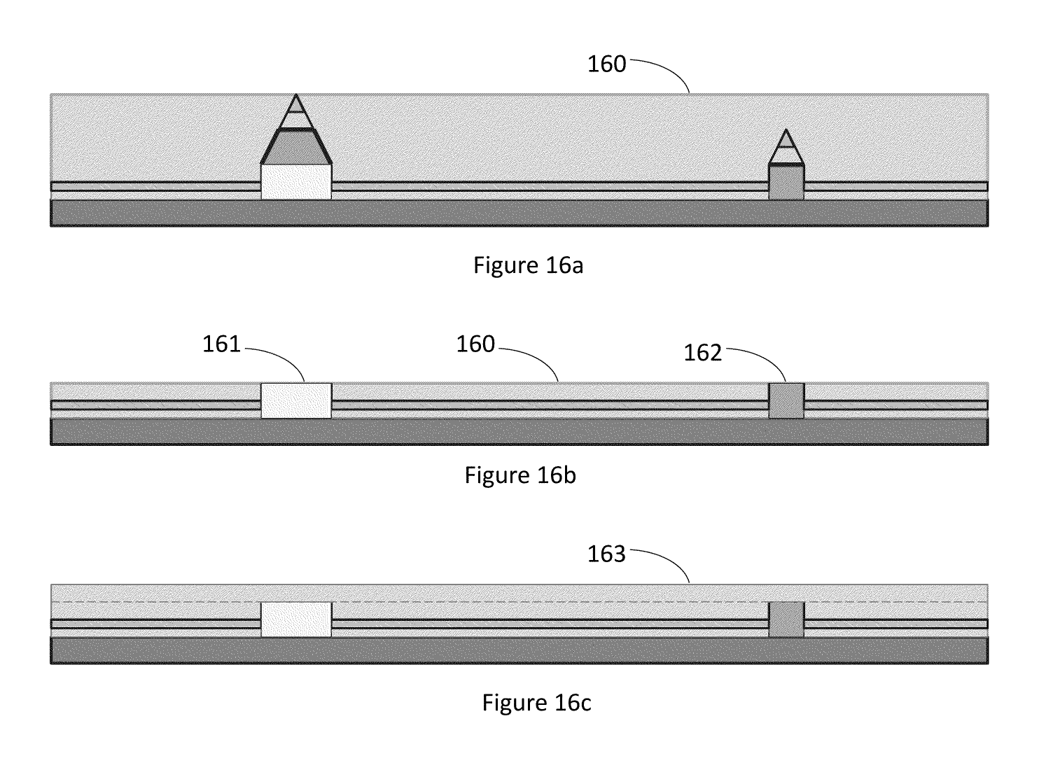

Reference is now made to FIG. 16a, an example of a cross-section of an antenna array, peeled from the stencil and flipped over, with an added cover glass layer, according to an embodiment of the invention. Optionally, this thick cover glass may be polished to remove the unnecessary layers down to the power 162 and ground 161 conductive materials, as shown in FIG. 16b, and an additional passivation material 163 may be added to cover the exposed conductive materials, as shown in FIG. 16c. It should be noted that the same materials and steps as described in the first process may be used in this fabrication process, and other fabrication steps may be added, or the steps described herein may be modified as necessary to improve the yield of the antenna arrays, or preservation of the stencils.

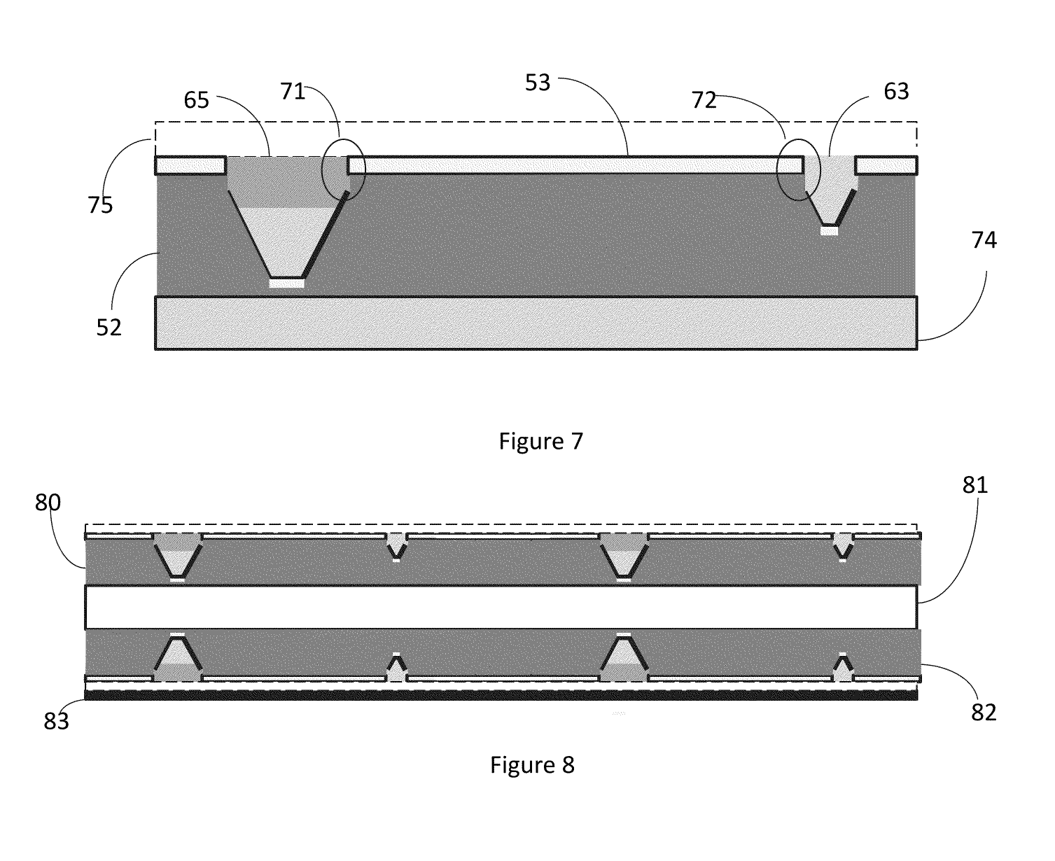

Reference is now made to FIG. 7, a Y cross-section of an example of a finished Solar antenna array, according to an embodiment of the invention. In this case, a clear cover layer 75 may be added to protect the array, and a solid back plate 74 may be attached to the polymer material 52 to make the structure more rigid. A MOM diode 71 may exist between the antenna 53 and the ground line 65, and another MOM diode 72 may exist between the antenna 53 and the power line 63, because of the oxide that was grown on the antennas. In another embodiment, the back plate 74 may be a mirror for reflecting light not absorbed by the antenna array. In yet another embodiment, the back plate 74 may be a conductive ground plane, and the polymer material 52 thickness may be adjusted for so that the antenna array may function as an optimal stripline antenna array.

Reference is now made to FIG. 8, which reflects an example of a further embodiment of the invention. A solar antenna array 80 may optimally absorb light polarized in the direction of the antennas (e.g., the Y direction), which is generally only ½ of the energy in sunlight. Other components, e.g., the X components, of the randomly polarized light from the sun may propagate through or reflect off the solar antenna array. Therefore, in another embodiment, two such solar antenna arrays, 80 and 82, may be sandwiched together with a light rotating material 81, such as liquid crystal between them. Furthermore, a layer of reflecting material 83 may be attached to the back side of the structure to reflect remaining light back into the sandwiched array. It is further contemplated that the polymer material 52 and conductive ground back plate 74 as shown in FIG. 7 may be optically transparent and may be included in such a sandwiched structure.

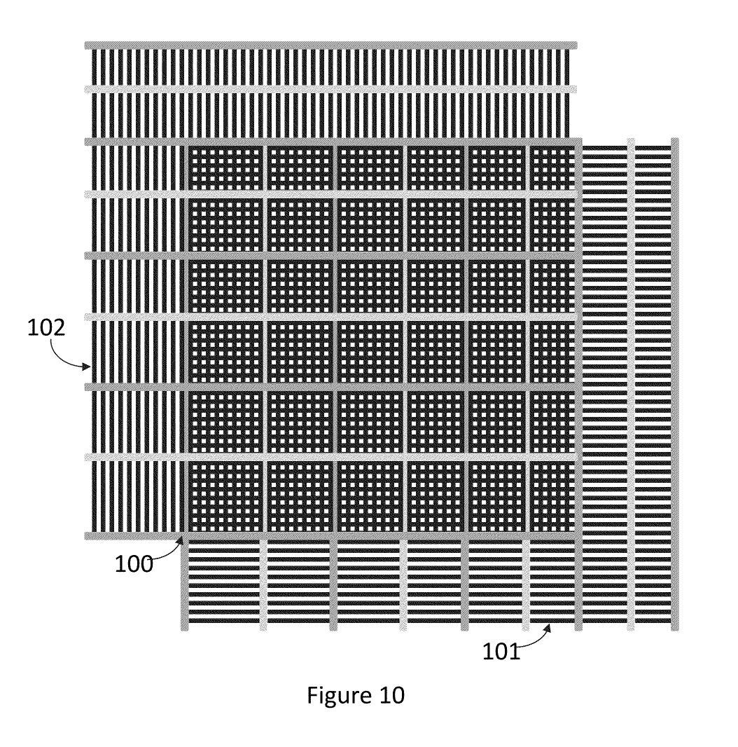

In yet another embodiment of the present invention, the material 81 may be optically clear, and the two solar antenna arrays 101 and 102, as shown in FIG. 10, may be sandwiched perpendicular to each other, as can be seen in the overlapping section 100.

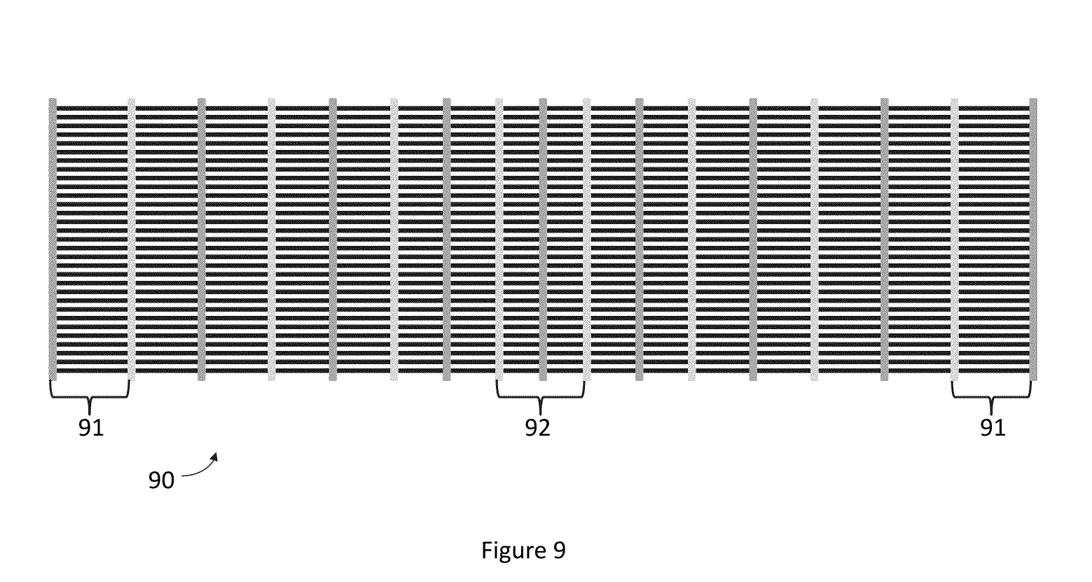

Reference is now made to FIG. 9, a top view of a section of an example of a solar antenna array, according to an embodiment of the invention. While the highest energy in visible light may generally be in the blue-green section of the spectrum (around 500 nm wavelength), it may be desirable to absorb as much of the visible spectrum as possible. It may, therefore, be desirable to vary the antenna length to cover most of the visible spectrum, e.g., from 400 nm to 720 nm. This may be accomplished by varying the sizes of respective rows of antennas back and forth across the array, from two ¼-wavelength sections of 100 nm each 92 up to two ¼-wavelength sections of 180 nm, or twice those dimensions if ground planes are not added to the array. The diagram 90 in FIG. 9 may be used to cover the spectrum from 400 nm to 720 nm in eight equal steps, though much finer variation in the step lengths and far more steps may occur before repeating, such that prisms may be employed to direction the proper frequency of light onto the most receptive antennas.

It will be appreciated by persons skilled in the art that the dimensions described in this invention may be difficult to fabricate, and may be prone to defects, particularly open circuits (“opens”) and/or short circuits (“shorts”) between the antenna and the power or ground lines.

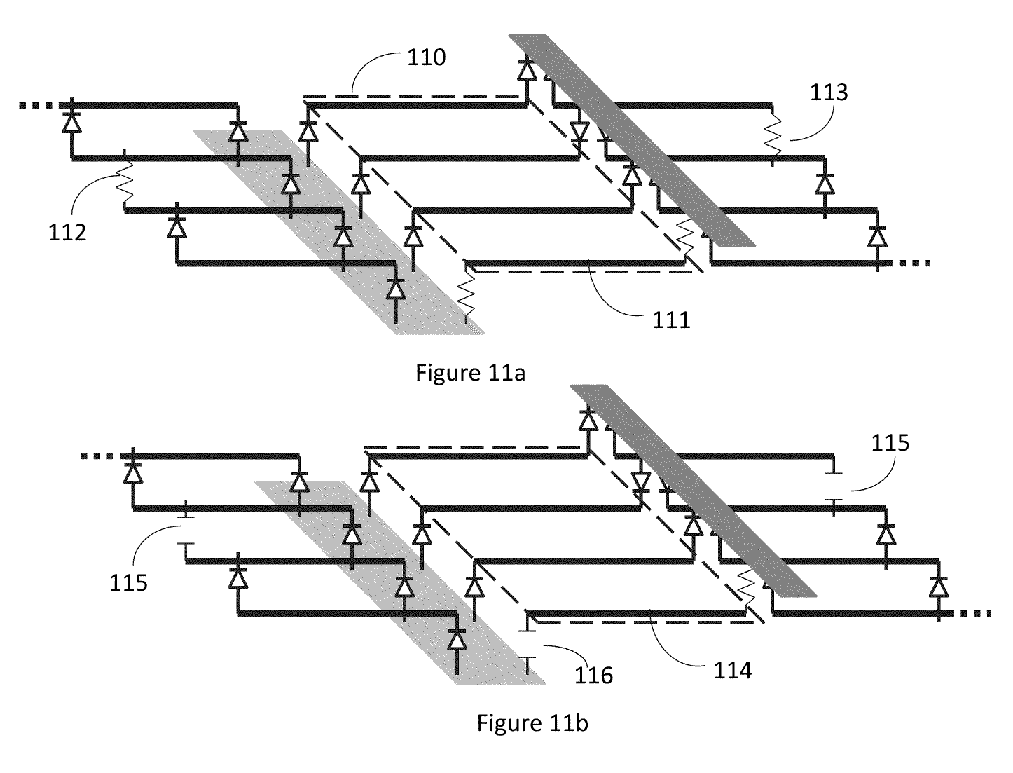

Reference is now made to FIG. 11a, a diagram of a section of an example of an antenna array according to an embodiment of the invention, where the antenna array is shown with defective diodes, depicted as resistors, connecting random antenna to power 112, or ground 113. In some cases, an antenna 111 may have two shorted diodes. Such defects may create shorts or partial shorts between the power and ground lines.

In another embodiment, the antenna arrays may be tested and fixed by applying a voltage between the ground and power lines sufficient to force a single tunnel diode past its negative resistance, but not sufficient to turn on good pairs of diodes. This may selectively drive current through the shorted defective diodes and may thereby heat the resistors sufficiently to open the short in a manner similar to a fuse, which may result in eliminating the shorts between power and ground,

Reference is now made to FIG. 11b, a diagram of a section of an example of the antenna array, according to an embodiment of the invention, where the antenna array is shown with defective diodes, which have been blown, and which are depicted as open capacitors 115, connecting random antenna elements to power 112 or ground 113. In an antenna with two shorted diodes 114, the weakest one of the resistors may blow 116, thereby eliminating the short.

In yet another embodiment, the antenna elements may be spaced close enough together to minimize the degradation of power production by the array due to the elimination of a random defective antenna.

In another embodiment of the invention, the antennas may be constructed out of carbon nanotubes grown between the power and ground lines. In this case the stencil may be primarily constructed out of equal depth V-grooves.

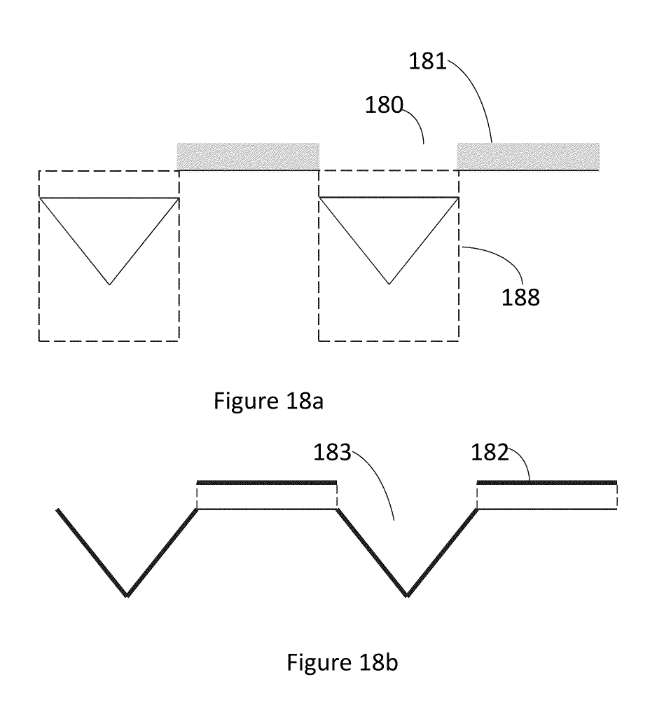

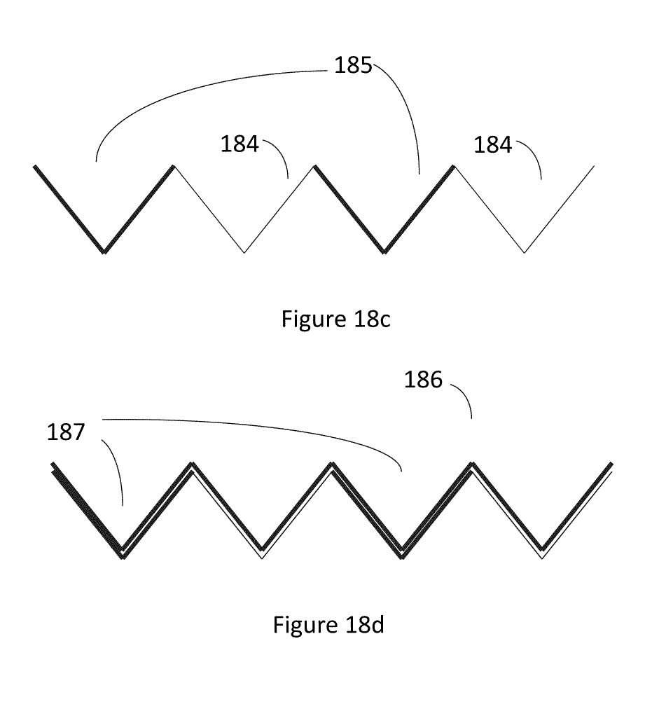

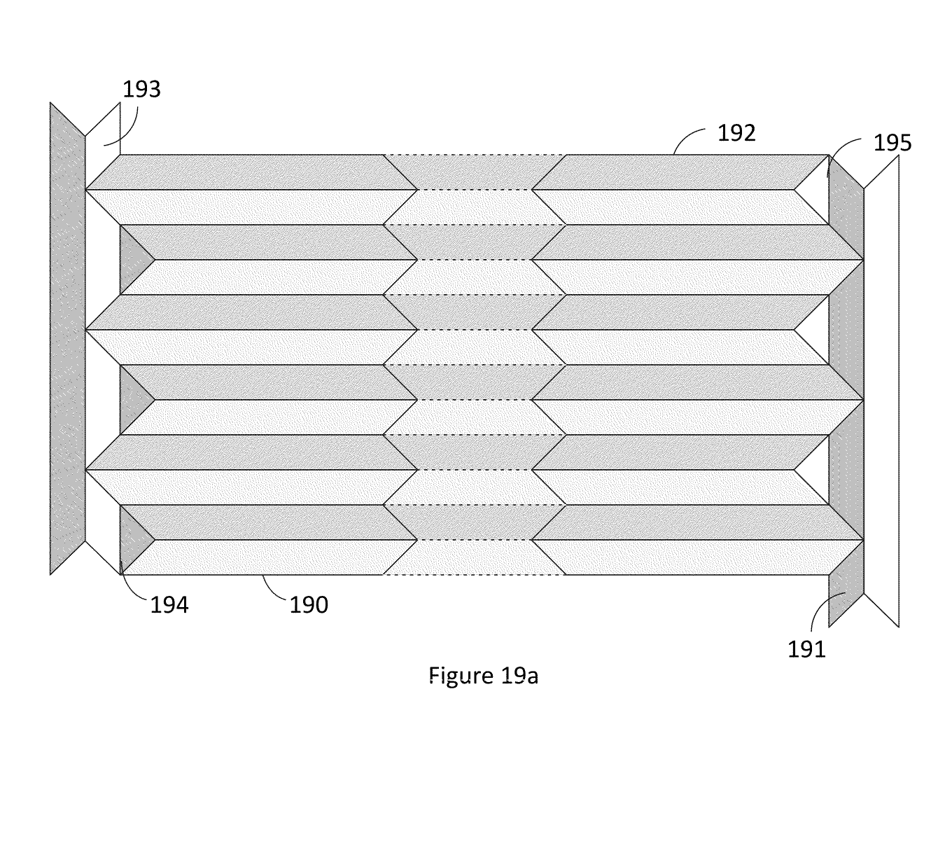

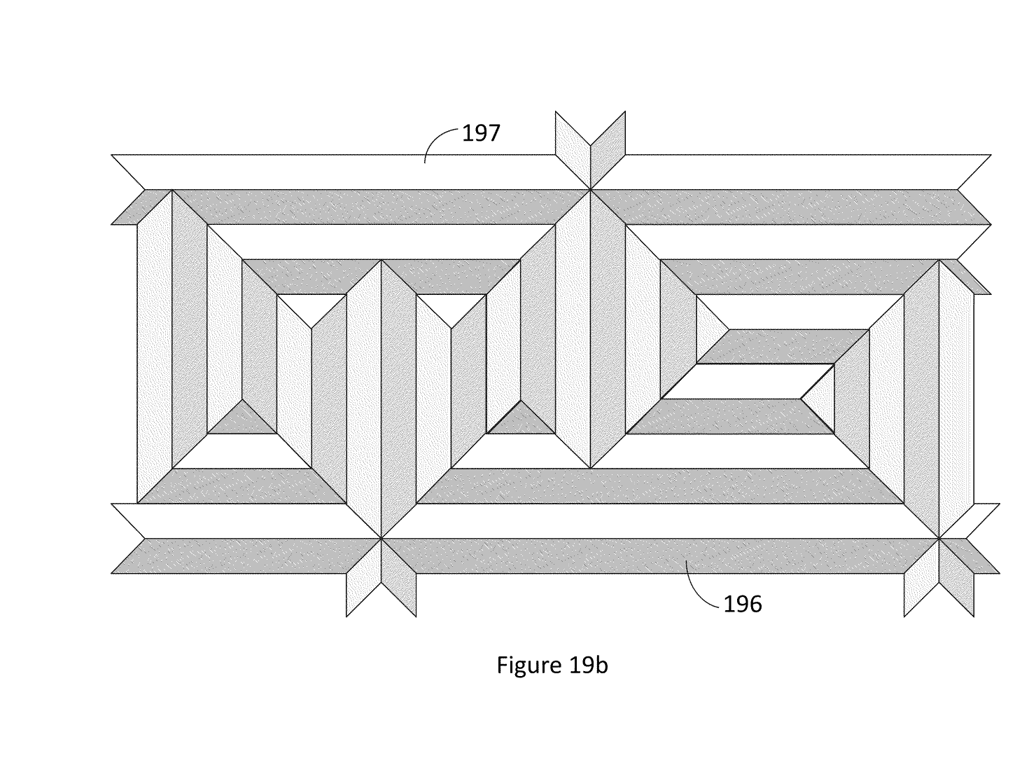

Reference is now made to FIGS. 18a through 18d, cross-sections of an example of the stencil fabrication. A regular width pattern may be exposed into resist 181, and a short vertical plasma etch followed by a subsequent V-groove etch may performed, leaving a first set of V-grooves 180 between the residual resist. Optionally, a p-doped wafer may be used to construct the stencil, and a selective n-doped diffusion may be performed 188 on the initial V-grooves. Thereafter, the cleansed wafer may be coated with a thin layer of a non-adhesive material such as Silicon Nitride (SiN) or Silicon Carbide (SiC), coating the first set of V-grooves 183 and the top surface of the wafer as shown in FIG. 18b. After polishing the wafer to remove the non-adhesive material on the un-etched surface 182, a second set of V-grooves 184 may be etched, leaving the first set 185 protected by the non-adhesive material, as shown in FIG. 18c. Finally an additional layer of non-adhesive material may be added to the wafer, covering all the V-Grooves 186, as seen in FIG. 18d. The first set of V-grooves 187 may be etched wider than the second set of V-grooves to compensate for the different thicknesses of the non-adhesive material. Alternatively, different non-adhesive materials, such as Silicon Nitride and Silicon Carbide, may be respectively deposited in the first 185 and second 184 sets of V-grooves. The resulting stencil contains power 190 and ground 192 V-groove fingers, each connected to power 191 and ground 193 V-groove ties, in an alternating fashion, with alternating breaks 194 and 195 at the other ends of the fingers, as seen in FIG. 19a. It is also contemplated that the V-groove fingers for power 196 and ground 197 lines may vary in the horizontal and vertical directions as seen in FIG. 19b

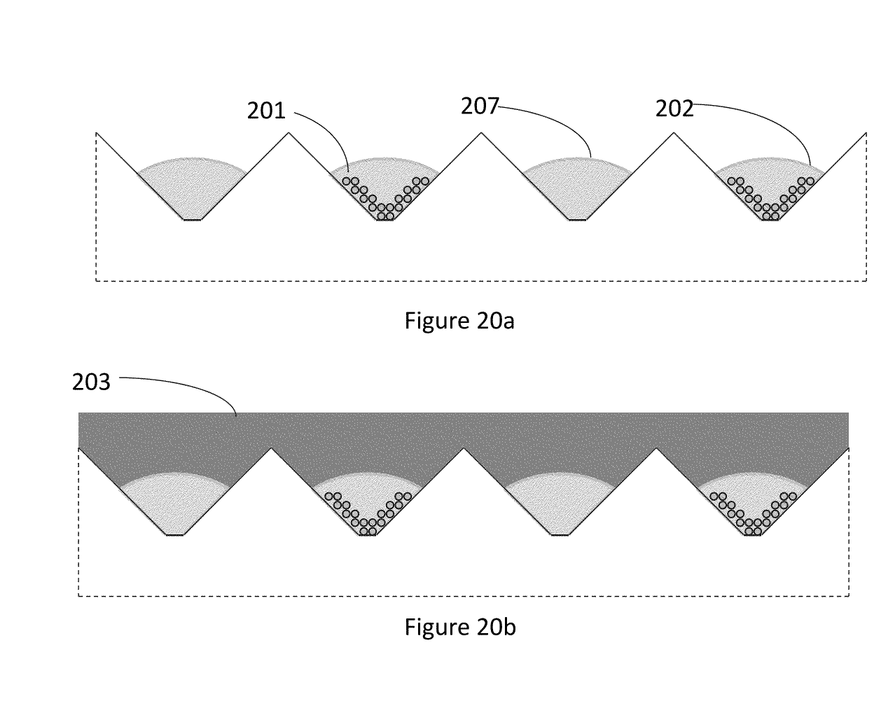

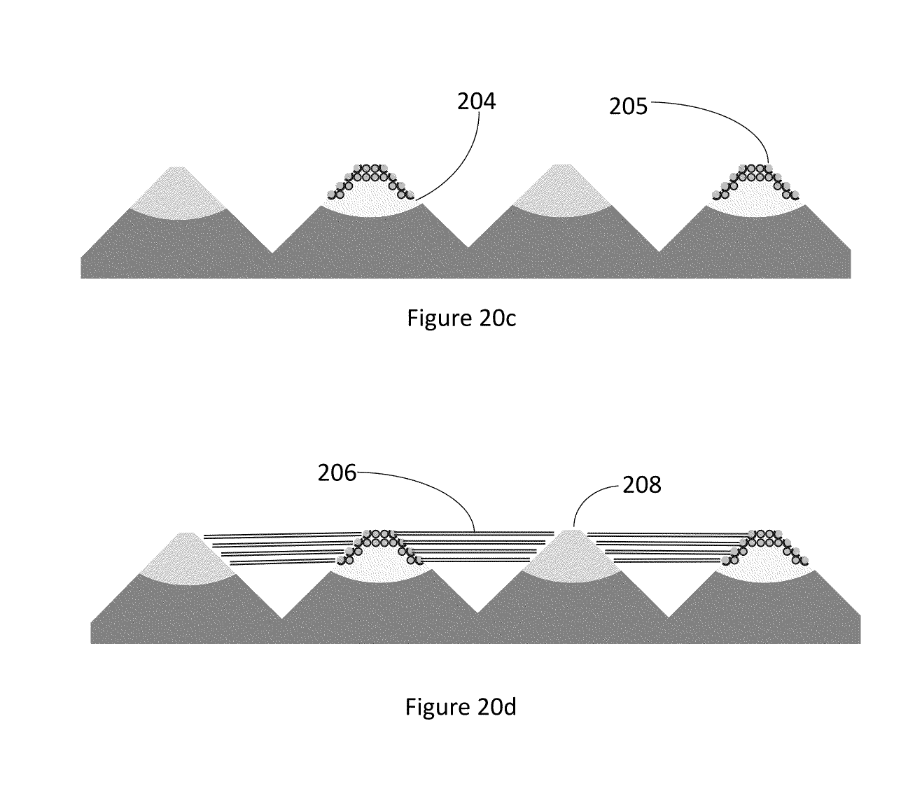

Reference is now made to FIGS. 20a through 20d, cross-sections of an example of an antenna array during its fabrication, according to an embodiment of the invention. Initially a carbon nanotube catalyst, such as iron, nickel, or some other magnetic metal may be arc sputtered onto the Stencil, forming a layer of small optionally, oxidized balls in the V-grooves. A conductor, such as gold, silver, aluminum or some other suitable metal or alloy, may be deposited in the V-grooves such that the catalytic balls 201 may be suspended on the edges of the conductor 202, as seen in FIG. 20a. Alternatively, the PN diode created between the two sets of V-grooves in the stencil may be reverse-biased, which may selectively deposit the carbon nanotube catalyst in some of the V-grooves 207. A polymer, such as polyamide or some other suitable material 203, may then be coated over the stencil, as seen in FIG. 20b. After curing the polymer 203, the entire structure may be removed from the stencil. Optionally, the oxidized balls 205 may be etched back, exposing the catalytic ball's metal, as shown in FIG. 20c. Thereafter, the power and ground lines may be heated and respectively charged to negative and positive voltages, an optional magnetic field may be applied, and a hydrocarbon, such as methane or acetylene, may be introduced into the deposition chamber to grow carbon nanotubes between the power and ground lines, as shown in FIG. 20d. The nanotubes may grow from the catalytic balls on the negatively charged power lines to the metal on the positively charged ground lines 208. Subsequent to connecting the nanotubes to the conductor, the conductor may be heated, which may anneal the carbon nanotubes into the conductive material.

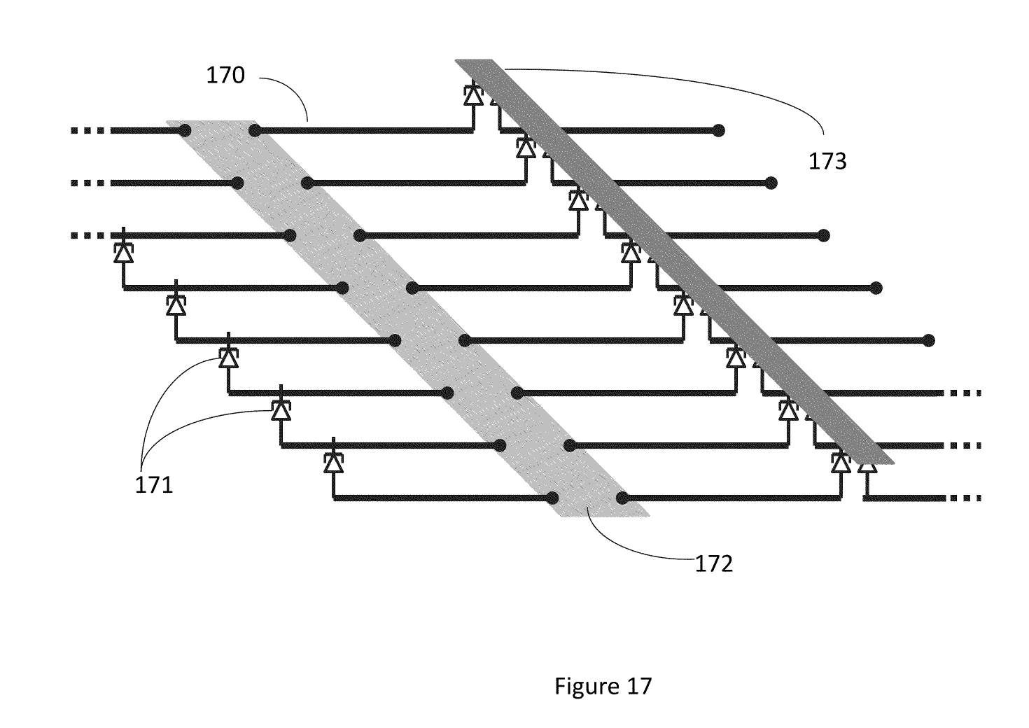

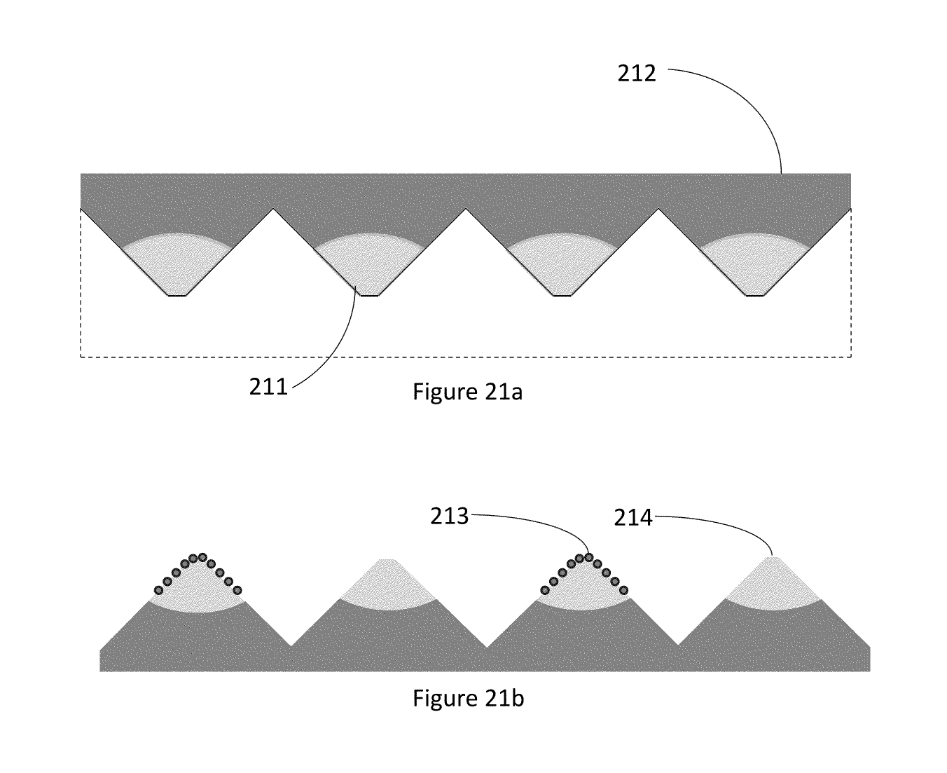

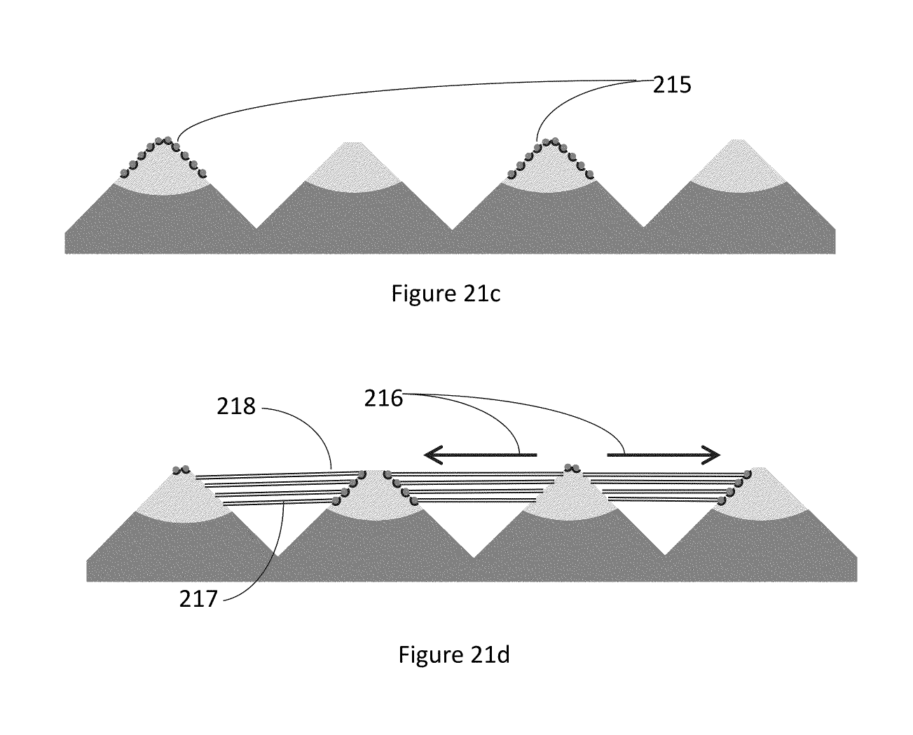

Reference is now made to FIGS. 21a through 21d, cross-sections of an example of an antenna array during its fabrication, according to another embodiment of the invention. In this embodiment the V-grooves may be filled with just a conductor 211, covered with a polymer 212, as shown in FIG. 21a, and removed from the stencil. The power and ground lines may then be respectively charged to negative and positive voltages, and charged oxidized catalytic balls may be selectively deposited on the ground lines 213, leaving the power lines 214 clear of the catalytic balls as shown in FIG. 21b. Thereafter, optionally, the exposed oxide may be etched off the catalytic balls 215 as shown in FIG. 21c. Subsequently, the carbon nanotubes may grow in opposite directions 218 from the ground lines toward the metal on the power lines, carrying the catalytic balls on the tips of the carbon nanotubes, such that the shortest carbon nanotubes 217 may connect first and the longer carbon nanotubes 218 may connect later, as seen in FIG. 21 d. The conductor, catalytic balls and the thin oxide may form a metal oxide metal (MOM) diode. In this manner, as seen in FIG. 17, rectifying MOM diodes 171 may be connected to the power lines 173 and the antennas 170, while the other ends of the antennas 172, may be connected to the ground lines. The diameter of the catalytic balls may determine the diameter of the nanotubes, the structure or chirality of the carbon nanotubes may in part be determined by the applied magnetic field, and the direction of growth of the nanotubes may be determined by the direction of the electric field between the power and ground lines, with the connections being made successively in order of their length, as may be seen in FIG. 21 d.

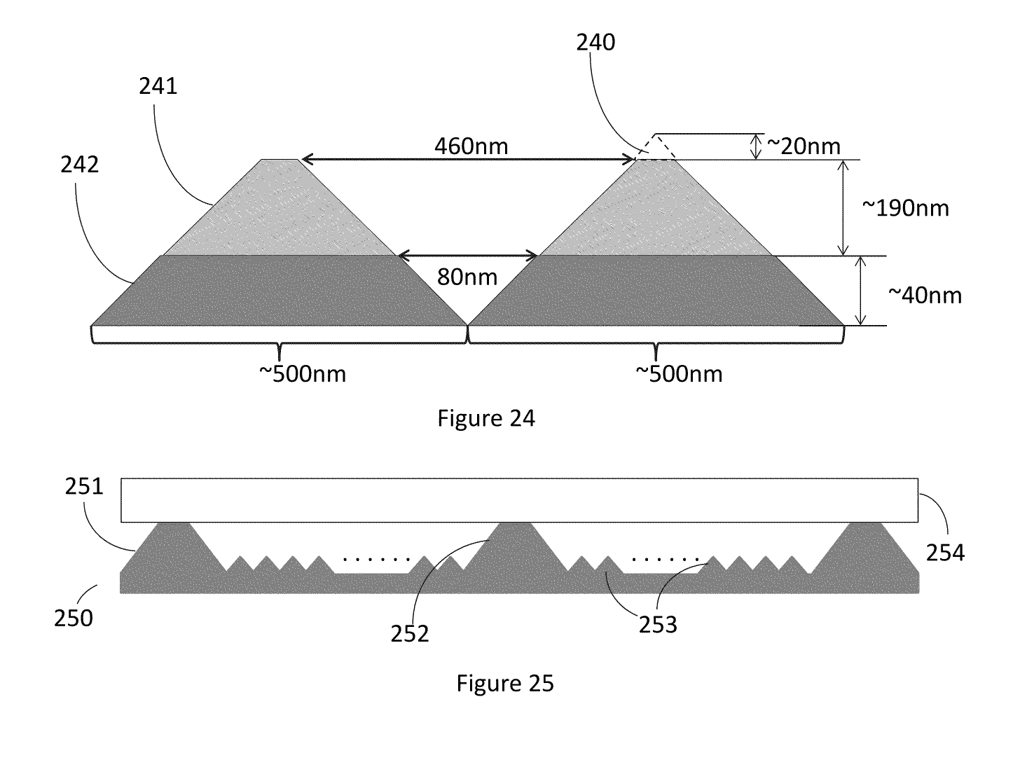

Reference is now made to FIG. 24, an annotated cross-section of an example of an antenna array, according to an embodiment of the invention. An antenna's efficiency to absorb electromagnetic frequencies may be significantly lower, the farther the electromagnetic frequency varies from the ideal frequency of the antenna, or the farther the electromagnetic waves are from the antenna. These effects may significantly limit the efficiency of a regular two-dimensional array of antennas with varying lengths. In order to absorb an optimal amount of the visible and infrared solar energy, the antennas may need to vary in length between 80 and 460 nanometers. The nanotubes may grow to distances between 80 and 460 nanometers in the direction of an electric field, which may be applied between conductors containing catalytic balls. The amount of growth may be related to strength of the electric field and the density of the catalytic balls, which may be chosen to maximize the efficiency of the resulting antennas. The power and ground lines of a solar antenna array may be constructed by depositing ˜190 nanometers 241 of catalytic balls and metal, followed by ˜40 nanometers of an insulating polymer 242, using a stencil with V-grooves that may have been constructed using an inexpensive mask with ˜½ micron dimensions, and may be coated with Silicon Nitride, Silicon Carbide and/or some other material that may be non-adhesive to the deposited conductor. The resulting power and ground lines may be as much as ˜20 nanometers 240 shallower than the originally etched V-grooves due to the coating and any optional etching.

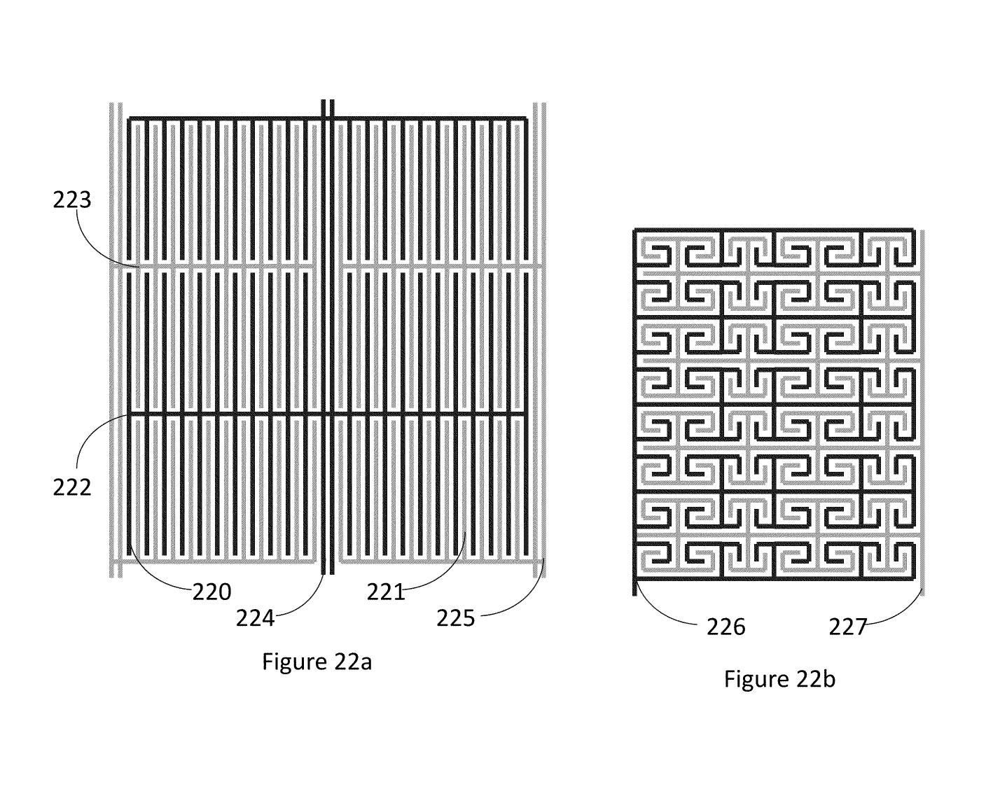

Reference is now made to FIGS. 22a and 22b, top views of two different configurations of the power and ground lines on solar array corresponding to the sections of stencils shown in FIGS. 19a and 19b. In either configuration the array may be limited to lines the size of the V-grooves because conductivity may require the height of the power and ground lines to remain the same throughout the array. In one configuration shown in FIG. 22a, the array may be composed of alternating fingers of power lines 220 and ground lines 221, with perpendicular ties 222 and 223, and possibly multiple ties 224 and 225 as needed, which may keep the current density and resistance low. In another configuration the array may contain a varying pattern of fingers of power 226 and ground 227 lines, which may locally balance the horizontal and vertical directions of the nanotube antennas, as shown in FIG. 22b. Such configurations may eliminate the need for two perpendicularly aligned panels sandwiched together.

It is also contemplated that probe pads and larger lines may be separately deposited on the array prior to initially charging the power and ground lines.

Furthermore, it is contemplated that the conductor may be silver, aluminum, platinum, or another alloy that may be oxidized in the same or adjacent process steps with respect to process steps that oxidized the catalytic balls. Growing the carbon nanotubes between the power and ground lines may then form MoM diodes between the power lines and the ends of the carbon nanotube antennas and carbon metal-oxide-metal diodes between the ground lines and the other ends of the carbon nanotube antennas, in a manner similar to the structure shown in FIG. 1.

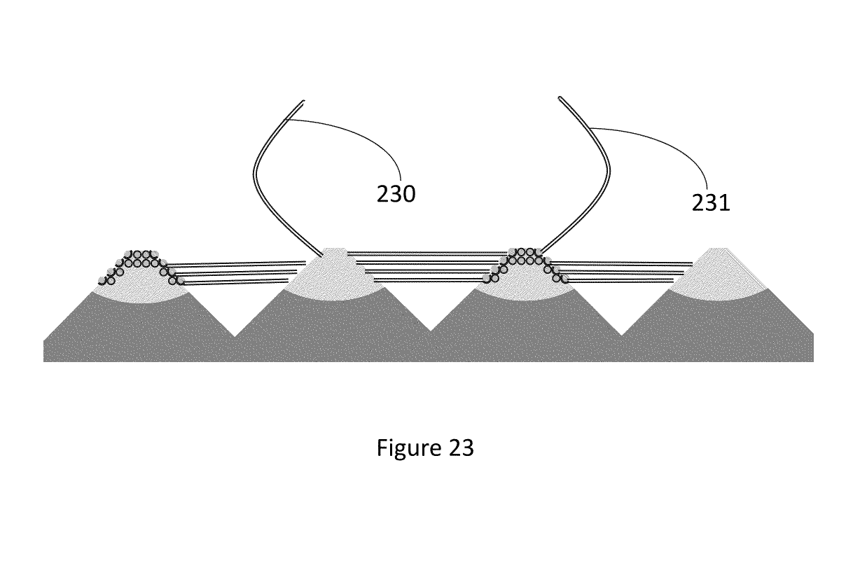

It is also contemplated that the process for testing and blowing shorted devices shown in FIGS. 11a and b may be applied to the carbon nanotube antennas, thereby opening at least one end of the defective antennas. Reference is now made to FIG. 23, a cross-section of an example of an antenna array with defective carbon nanotube antennas. Subsequent to the construction of the solar antenna array, some individual nanotubes may be incompletely or incorrectly connected to the power 230 and/or ground lines 231. They may be tested and corrected using the following steps:

A: turning the solar array upside down,
B. grounding both the power and ground lines,
C. moving a positively charged source below and across the antenna arrays, such that the loose nanotube is pulled behind the side of the power or ground line it is connected to, thereby breaking the nanotube free, and
D. removing any loose nanotubes, which break off the array.

In another embodiment of the current invention, larger structures may support a cover plate over the array to protect the antennas, the power and the ground lines from the external environment. Reference is now made to FIG. 25, a cross-section of an example of an antenna array with a cover plate. By etching a large V-groove around the outside of the stencil, a large board line may 251 may be created by the polyamide. Large V-groove squares may also be etched periodically across the stencil, which may create a regular array of large polyamide pyramids or posts 252 between the power and ground lines 253 on the antenna array 250, upon which a supporting transparent glass (or other material sufficiently transparent to permit light to pass through) plate 254, may placed to protect the antenna array. Optionally, if the polyamide may be sufficiently transparent, the glass plate may be replaced with a reflective mirror, which may reflect light that may have entered the array through the polyamide back onto the antennas.

It will be appreciated by persons skilled in the art that the present invention is not limited by what has been particularly shown and described hereinabove. Rather the scope of the present invention includes both combinations and sub-combinations of various features described hereinabove as well as modifications and variations which would occur to persons skilled in the art upon reading the foregoing description and which are not in the prior art.

We claim:

1. A solar antenna array configured to convert sunlight into electrical power, comprising:
uniformly horizontally spaced alternating power and ground lines, with sloped sides, and
carbon nanotube antennas of vertically varying lengths connected between the power and ground lines.

2. The solar antenna array as in claim 1, wherein
the power and ground lines further comprise a conductive metal.

3. A solar antenna array as in claim 2, wherein the conductive metal comprises at least one of the group consisting of gold, silver, platinum, copper and aluminum.

4. A solar antenna array as in claim 2, wherein one of the power and ground lines further comprise catalytic balls.

5. A solar antenna array as in claim 3, wherein the catalytic balls comprise a magnetic conductive metal coated with an oxide.

6. The solar antenna array as in claim 5, wherein the conductive catalytic balls comprise at least one substance selected from the group consisting of nickel, iron and cobalt.

7. The solar antenna array as in claim 1, wherein the antennas of different lengths are configured to cover at least two regions of the light spectrum.

8. The solar antenna array as in claim 1, wherein the antennas of different lengths are locally aligned in at least two directions.

9. The solar antenna array as in claim 8, wherein the two directions are perpendicular to each other.

10. A method of constructing a solar antenna array, the method including:
creating a stencil on a silicon wafer,
depositing layers of metal and insulating polymer on the stencil,
separating the array from the stencil,
growing carbon nanotubes between oppositely charged lines of catalytic balls and metal, and
removing defective carbon nanotubes.

11. The method as in claim 10, wherein creating the stencil includes:
exposing a pattern of lines in resist coated on the silicon wafer,
performing a first V-groove etch on the pattern of lines to obtain first V-grooves,
coating the first V-grooves with silicon nitride,
removing the silicon nitride from the un-etched surface of the silicon wafer,
performing a second V-groove etch on the un-etched surface to obtain one or more second V-grooves, and
coating the wafer with a second layer of at least one of silicon nitride or silicon carbide.

12. The method as in claim 11, wherein the silicon wafer is a p-doped silicon wafer and the first V-groove etch includes an n-doped diffusion.

13. The method as in claim 11, wherein the coated first and second V-grooves have a common width.

14. The method as in claim 10, wherein depositing layers of metal and insulating polymer includes:
depositing a conductive metal using low-pressure chemical vapor deposition (LPCVD),
simultaneously are sputtering and oxidizing balls of a catalytic metal, and
depositing an insulating polymer.

15. The method as in claim 10, wherein depositing layers of metal and insulating polymer includes:
applying a voltages on the n-doped diffusion and the p-doped silicon wafer to reverse-bias the PN diode.
depositing a conductive metal using low-pressure chemical vapor deposition (LPCVD),
simultaneously are sputtering and oxidizing balls of a catalytic metal selectively on one of the first and second V-groves, and
depositing an insulating polymer.

16. The method as in claim 10, wherein growing carbon nanotubes includes:
applying a negative voltage on the power lines and a positive voltage on the ground lines,
heating the power lines,
filling a chamber containing the solar cells with a hydrocarbon gas, and
continuing the applying a negative voltage and a positive voltage, the heating the power lines, and the filling the chamber until the carbon nanotubes have grown between the power and ground lines.

17. The method as in claim 10 wherein depositing layers of metal and insulating polymer includes:
depositing a conductive metal using low-pressure chemical vapor deposition (LPCVD), and
depositing an insulating polymer.

18. The method as in claim 17, wherein growing carbon nanotubes includes:
applying a negative voltage on the power lines and a positive voltage on the ground lines,
selectively depositing charged oxidized catalytic balls on the power lines,
etching oxide from exposed surfaces of the catalytic balls and conductive metal,
heating the power lines,
filling the chamber containing the solar cells with a hydrocarbon gas, and
continuing the etching oxide, the heating the power lines, and the filling the chamber until the carbon nanotubes have grown between the power and ground lines.

19. The method as in claim 17, wherein growing carbon nanotubes includes:
applying a negative voltage on the power lines and a positive voltage on the ground lines,
selectively depositing charged oxidized catalytic balls on the power lines, heating the power lines,
filling the chamber containing the solar cells with a hydrocarbon gas, and
continuing, the heating the power lines, and the filling the chamber until the carbon nanotubes have grown between the power and ground lines.

20. The method as in claim 10, wherein removing defective carbon nanotubes includes:
heating the ground lines to anneal the carbon nanotubes to the metal,
flipping over the solar array,
grounding the power and ground lines,
disconnecting one or more loose carbon nanotubes by moving a positively charged source across the array perpendicular to the direction of the power and ground lines, from a side of a line containing the one or more loose carbon nanotubes towards an opposite side of the line, and
removing the resulting one or more disconnected loose carbon nanotubes.
